(19) United States
(12) Patent Application Publication
(10) Pub. No.: US 2019/0042679 A1
(43) Pub. Date: Feb. 7, 2019

(54) METHOD FOR VIRTUAL TESTS FOR AN AUTONOMOUS VEHICLE

(71) Applicant: FORD GLOBAL TECHNOLOGIES, LLC, Dearborn, MI (US)

(72) Inventors: Frederic STEFAN, Aachen (DE); Alain Marie Roger CHEVALIER, Henri-Chapelle (BE); Evangelos BITSANIS, Aachen (DE); Michael MARBAIX, Haillot (BE)

(73) Assignee: FORD GLOBAL TECHNOLOGIES, LLC, Dearborn, MI (US)

(21) Appl. No.: 16/052,790

(22) Filed: Aug. 2, 2018

(30) Foreign Application Priority Data
Aug. 7, 2017 (DE) 10 2017 213 634.0

(51) Int. Cl. G06F 17/50; G05D 1/00

(52) U.S. Cl. CPC G06F 17/5009; G06F 3/014; G05D 1/0088

(57) ABSTRACT

A method for testing a virtual, autonomously driving, tested vehicle is carried out in a virtual test environment on a computer. The method comprises installing and operating software of the autonomously driving, tested vehicle in the computer. Installing and operating a virtual test scenario in the computer includes defining at least one variation point, at least one validation point, at least one drive command point, and analyzing the variation, validation and drive command points.

### CROSS-REFERENCE TO RELATED APPLICATIONS

This application claims foreign priority benefits under 35 U.S.C. § 119(a)-(d) to DE Application 10 2017 213 634.0 filed Aug. 7, 2017, which is hereby incorporated by reference in its entirety.

### TECHNICAL FIELD

The disclosure relates to a method and a device that carries out virtual tests in a virtual reality environment for a vehicle having automated driving functionality.

### BACKGROUND

In autonomously driving vehicles, development and testing of software is faced with new demands. Because of algorithms that are used for automated control, a variety of results during a design phase and a variety of tests is necessary. In conventional development, in contrast, vehicle tests are, more or less, predetermined, based on several selected applications, which are specified during development and design. In a predefined number of applications that relate to specific scenarios and situations, the software, which will be implemented in the vehicle, has to be capable of coping with greatly varying applications.

For autonomously driving vehicles, previous approaches of conventional development represent an excessive number of restrictions. Thus, for example, the number of scenarios that autonomous driving has to cope with is substantially greater and almost infinite. According to the previous approaches, this requires an exceptionally large number of driven test kilometers and thus a substantial time. Such tests also require an environment that offers a high level of flexibility in order to test a maximum number of situations (e.g., different gradients, different obstruction layout, various road surfaces . . . ) in a reasonable time span. This flexibility is linked to high costs (i.e., travel, transportation of material, installation, materials, public road certifications . . . ). A definition of a large number of scenarios generally takes place in text form, which relates to a special software language. Because of the number of the scenarios to be handled, this can become a very complex task.

In general, vehicle tests have previously been carried out in the real world, at least and in particular in a late phase of development. This firstly requires that a physical prototype is present and implemented with realistic hardware. This is a costly process. It requires time, resources, money, etc. Many questions that arise or occur during a design phase can frequently, only be answered very late in the development process. Many different traffic situations, for example, dense, inner-city traffic, freeway, curvy hill route, make it nearly impossible because of the complexity thereof to be able to take into consideration all possible situations during a test phase.

DE 10 2011 088 807 A1 describes a method for developing and/or testing a driver assistance system, in which a plurality of further test scenarios is prepared from a predefined test scenario by means of the Monte Carlo simulation, i.e., a stochastic method. A curve with and a curve without intervention of the driver assistance system is respectively simulated for each scenario prepared. It is possible by way of a comparison of these two scenarios to find quantitative amounts for effects of intervention of the driver assistance system. For example, a risk of accident, a risk of damage, or the like can be quantified for each of the scenarios.

DE 10 2008 027 509 A1 discloses a method that also relates to a driver assistance system. The driver assistance system is already able to be evaluated with respect to its effectiveness in a planning phase. A simulation that is based on measurement data of a real accident is carried out for this purpose. At decisive points of the simulation, a sub-simulation is generated that includes the intervention of a driver assistance system. This intervention can include, for example, activation of an automatic braking system using different decelerations. The results, or the output, of the accident situation are stored as a simulation dataset. With respect to the accident used as the basis, data of which were used for simulation, activation times corresponding to different decelerations, for example, that result in an avoidance of the accident, can thus be computed for an automatic braking system. In this manner, a database of simulation datasets is provided, which can be used for a plurality of driver assistance systems in order to obtain a reliable statement, based on real data, about effectiveness of the driver assistance system. It is disadvantageous that only measurement data of actually occurring accident situations are accessed. Scenarios for which no accident data are provided, data of a driving situation in which loss of vehicle control has not occurred, and/or from successfully prevented accidents or “almost” accidents are not used in the proposed method. Therefore, an array of measurement data that would possibly be entirely suitable for preparing further test scenarios is discarded. In particular, a critical range between an accident prevented by a driver assistance system and occurring accident or loss of control is a range that carries the greatest possible potential for development or refinement during testing.

### SUMMARY

It is a goal of the disclosure to propose a method to develop and carry out virtual tests in a virtual reality environment, in order to thus check and validate automated driving software, or as much as possible to answer every type of question that could arise during a design phase. The method is to offer all required flexibility in order to test or simulate automated driving, and is to require neither a physical vehicle nor a physical test environment that simulates traffic.

Exemplary embodiments and more detailed explanations of the disclosure result from the following description of an exemplary embodiment of the disclosure, which is not to be understood as restrictive and explained in greater detail with reference to the Figures.

### BRIEF DESCRIPTION OF THE DRAWINGS

FIG. 1 shows a block diagram of a system used for the disclosure;

FIG. 2 shows a three-dimensional illustration of a virtual test scenario;

FIG. 3 shows the illustration according to FIG. 2, but now having incorporated definitions of variable points;

FIG. 4 shows the illustration according to FIG. 3, but having a different selection of the variable points; and

FIG. 5 shows the illustration of FIG. 4, again having a different selection of the selected points.

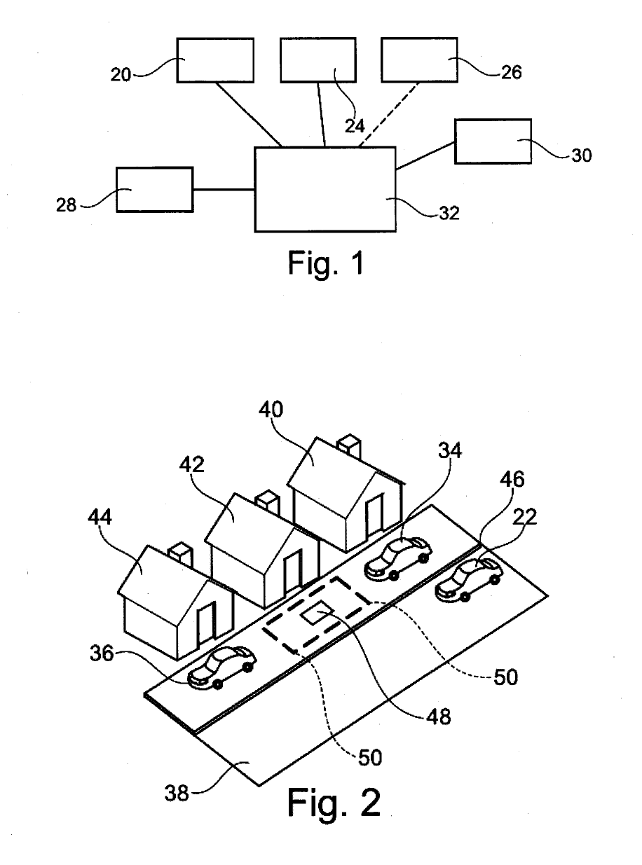

### DETAILED DESCRIPTION

As required, detailed embodiments of the present disclosure are disclosed herein; however, it is to be understood that the disclosed embodiments are merely exemplary of the disclosure that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present disclosure.

The disclosure presumes that the definition of a virtual test scenario for a vehicle is known from the prior art. The method according to the disclosure proceeds as follows:

In block 20, a virtual test scenario for an autonomously driving vehicle 22 to be tested is defined and selected.

In block 24, variation points are defined and selected. They enable a large number of tests to be derived from a test scenario.

In block 26, special validation points are defined and selected, which enable a particular element of a virtual world to be marked, which is relevant for validation and verification methods.

In block 28, drive command points are defined and selected, which enable several simple instructions to be given, and when and/or where certain algorithms of the vehicle 22 to be tested are activated.

In block 30, a validation and verification method is defined and selected, which enables an evaluation of each check, or each test to be carried out.

Block 32 provides usage of a virtual reality interface, in order to enable a seamless, efficient, and ultrafast definition of each test.

The individual blocks and in particular a function thereof will be described hereafter. Each block stands for an electronic unit, which comprises software and is implemented in an electronic computer:

Block 20 represents a virtual test scenario A definition of a virtual test scenario that can consist of the following elements: definition of active road users, one or more vehicles 22 in each test, a definition of passive road users, and all other road users who move in a traffic space, but are not being tested and can possibly interact with the tested vehicle 22, for example, pedestrians, bicyclists, other vehicles 34, 36, animals . . . etc.

A definition of a virtual environment may consist of the following elements: a virtual road 38, a virtual infrastructure definition (signs, traffic signals . . . ), virtual obstructions (walls, fences, trees, houses 40, 42, 44, curbstone 46, parking spaces 48, holes . . . ), virtual weather, etc.

Block 24 represents definition and selection of variation points. In selection of an arbitrary element of the virtual test scenario, a test designer can link one or more variation rules for one or more features of selected elements. Each variation rule can consist of associating a marking with an element of the virtual test with aid of a virtual reality interface (see block 36), and defining a value range for one or more features of the element (see block 36). Examples of variations that can be linked to a variation point positioned on test elements are listed in the following table:

| Elements of a virtual | |
|---|---|
| test scenario linked | Variation points for specific elements |
| to variation points | of the virtual test scenario |
| Tested vehicle 22 | Control and monitoring algorithms (for example, |
| | longitudinal control, control of the straight-ahead |
| | travel, software of the tested vehicle 22 |
| | Sensor models (e.g., radar, brake pressure . . .) |
| | Actuator models (e.g., drive motor, brakes, |
| | steering . . .) |
| Passive test | Behavior model (passive, aggressive, |
| participant | unpredictable . . .) |
| | Movement lines (navigation in a virtual test) |
| | Dimensions (size, shape) |
| | Recognition features (material, color, model . . .) |
| Virtual | Properties of a road (gradient, surface, width, |
| environment | adhesion . . .) |
| | Features of an infrastructure (type of traffic signs, |
| | chronological behavior of traffic signals . . .) |
| | Features of obstructions (dimensions, surface, |
| | friction . . .) |
| | Weather conditions (wind speed and direction, |
| | rain, snow, fog . . .) |

In a further implementation, the variation point could preferably include software calibration.

Block 26 represents definition and selection of the validation points. Validation points are markers that are linked to any type of elements of the virtual scenario via a virtual reality interface. Validation points are a method for definition of an additional evaluation criterion for evaluation in block 30, this block also carries out the evaluation, inter alia. There are positive and negative validation points. Positive validation points are linked to a positive score. Negative validation points are linked to a negative score. KO validation points may also be linked to a score for definition of additional evaluation criterion.

If, during a test, the tested vehicle 22 comes into contact with an element that is linked to a validation point, the tested vehicle 22 will receive a corresponding validation point and score. If the element associated with the validation point is, for example, a horizontal surface such as a parking space 48, the tested vehicle 22 has to cover a large part of this surface (see example below) in the virtual test environment in order to receive corresponding points.

Block 28 represents drive commands. In a traditional approach, a test engineer defines so-called test steps, which are a sequence of actions that are applied to an object to be checked (for example, the tested vehicle 22). The sequence of actions generally comprises a special interaction with an environment (for example, the tested vehicle 22 drives at 50 km/h and a second vehicle stops 50 m in front of the tested vehicle 22). Since automated vehicle software is inherently designed in such a manner that it can interact with an environment, a simpler approach can be used, including definition of drive commands. Each individual drive command is an element that is positioned by a virtual reality interface in the virtual test scenario. There are many types of travel instruction points, discussed below.

Starting points, which describe coordinates at which the tested vehicle 22 is to start a test, or reposition itself if it leaves boundaries of the virtual test scenario environment. A starting point is generally linked to instructions that “start a vehicle” (ON button, activation of a specific part of control software). If the test is to be carried out with multiple vehicles, multiple starting points can be defined, and one starting point can be linked in each case to a tested vehicle 22. In this case, a certain probability for movement can also be used. In general, each individual tested vehicle 22 has a separate starting point, however, starting points can also coincide.

Software activation points, which describe coordinates, or a time in which specific parts of software provided in the tested vehicle 22 are activated (for example, activate independent parking, activate coasting, activate lower travel velocity . . . )

Route points describe a route in the virtual test environment that the tested vehicle 22 is to reach. At least one route point can be associated with an individual tested vehicle 22, wherein each route is linked to a certain probability, and therefore each individual tested vehicle 22 can also select an alternative path. Route points can be compared to a type of virtual navigation system. Each route point or waypoint linked to each individual tested vehicle 22 can also be linked to a predefined time span that the tested vehicle 22 is to maintain. Each route begins from a starting point. The tested vehicle 22 can either return thereto or can end its trip at another point of the virtual test environment. If a tested vehicle 22 has reached a waypoint, it returns to one of its starting points or travels to a next waypoint with the probability linked thereto.

Block 30 represents an evaluation, which includes generic evaluations and special evaluations tied to a demand. Since automated driving software is capable, on one hand, of managing every interaction with the environment and, on the other hand, is supposed to offer a certain travel comfort, acceptance criteria of the test can be generic and identical for all test persons, which is defined as a generic evaluation. There is generally no necessity of establishing specific acceptance criteria in a generic evaluation. In this case, the generic acceptance criteria can be given by a collection of traffic rules (for example, no contact with another road user, stopping at a traffic signal, right-of-way for traffic coming from the right . . . ), and a collection of travel comfort rules, which are composed at least by analysis of acceleration and jerking travel (abrupt variation of acceleration over time), wherein excess acceleration, strong braking, and jerking can be perceived very negatively by passengers, in particular, if the excess acceleration, strong braking, and jerking exceed certain thresholds.

The disclosure proposes preparing a classification of both every traffic rule and every comfort rule, and linking a specific number of points with each of them. This enables a standardized option to be defined, and a capability of comparing automated software algorithms. At an end of a test, an overall evaluation that is achieved by the algorithms is estimated by the test environment and reported to the test designer. This score can be scaled in relation to a performance and/or a duration of soft drive algorithm activation, and in relation to the performance and/or duration of associated rules. At the end of the test, the algorithm ascertains a specific total score, and outputs the specific total score to the test designer. The designer has an option of activating and/or deactivating certain rules if they are not relevant for software implemented in the tested vehicle 22.

In addition, the evaluation can also have a part specially tailored to a specific demand, which defines a special evaluation to meet a demand discussed above. The special evaluation tied to a demand is determined and defined by specially predefined validation points, see block 26.

At the end of the test, the test environment ascertains the score that is linked to validation points for each test repetition. A test can be considered to be passed if the score of a test event exceeds a certain threshold value. The test can be considered to be failed if a KO validation point was collected during one of repeated tests. All tests can be considered to be failed if something clearly indicates that the algorithm implemented in the tested vehicle 22 is not capable of correctly handling a specific situation. The individually-tailored evaluation method offers a rapid and simple possibility for validating, checking, and testing hypotheses during a development cycle.

The block 32 represents virtual reality interface (VR interface). The virtual reality interface is a graphic interface that enables a user to access any element of the virtual test scenario without problems, and assign the element to various variation, validation, and drive command points. An assignment can take place by selecting one of the points and positioning the point on a specific element of the virtual test definition. In a preferred implementation, this task can be carried out by a virtual reality interface (virtual reality spectacles, interactive holography, haptic gloves . . . ), via which the test designer is linked to a world of the virtual test definition. Use of haptic gloves enables a driver to “touch” the points and various elements of the virtual test scenario. As soon as a point is positioned, the test designer can select the point and open the point in order to configure the point (for example, give it a value range for a feature, define a score . . . ). The opening of a point can be carried out, for example, by using a specific gesture on the element using haptic gloves. As soon as the point is opened, the test designer can override properties to be processed and set them using another gesture to another specific value, or to another range of values. The following example contains several details for use of the VR interface. This method can also be applied on a conventional graphic interface of a desktop computer, a tablet, or the like.

In the example, a development team wishes to test a strategy for a fully-automated parking assistant at a vehicle level in an early phase of a project, in which a physical prototype and a real test environment do not yet exist.

Definition of the virtual test scenario, see FIG. 2: The test designer prepares a new virtual test scenario from an asset library for a VR environment. He sets specific elements in a test scene: a road 38, a curbstone 46, a first parked vehicle 34, a second parked vehicle 36, a parking space 48, a first house 40, a second house 42, and a third house 44. Furthermore, he sets a vehicle 22 to be tested and defines two boundaries 50, which respectively represent a distance between the parking space 48 and the two parked vehicles 34, 36. They will be used later to emulate different individual distances to the parked vehicles 34, 36. The test scenario can also be visualized on a holographic table.

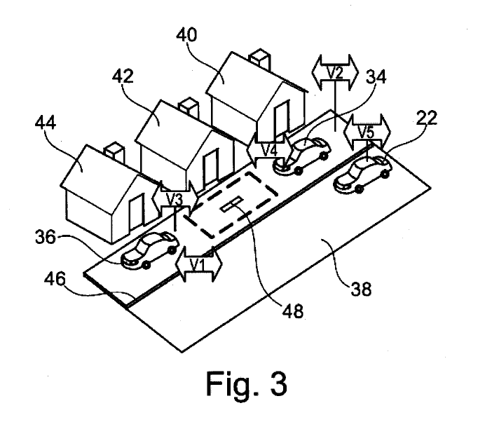

Definition of the variation points: The designer is interested in checking and validating the software for a variety of variations. The test designer calls up individual variation points in a VR world and links them to a desired element of the scene, see FIG. 3. The variation points include a variation point V1 being assigned to the road 38, a variation point V2 being assigned to the curbstone 46, two variation points V3 and V4 being assigned to the boundaries 50, and a variation point V5 being assigned to the tested vehicle 22.

The test designer selects each, individual, one of five variation points, and specifies the following features for the variation: a road gradient V1 varies from −15% to +15% in steps of 1% (31× combinations), and a height V2 of the curbstone 46 varies from 0 cm to 15 cm with a step of 1 cm (16× combinations). The boundaries 50 are set from a distance, indicated by V3 and V4, of 20 cm (very narrow) to 100 cm (very large) in relation to a respective, parked vehicle 34 or 36 with a step of 10 cm (9× combinations), wherein a space in front and behind a parked, tested vehicle 22 on the parking space 48 is thus determined. Association of two different sets of parking sensors, two different braking methods, three different items of software for parking assistance (total of 16× combinations) is generally indicated by at V5. Therefore, a total of 31×16×9×16=71,424 individual test results to be carried out.

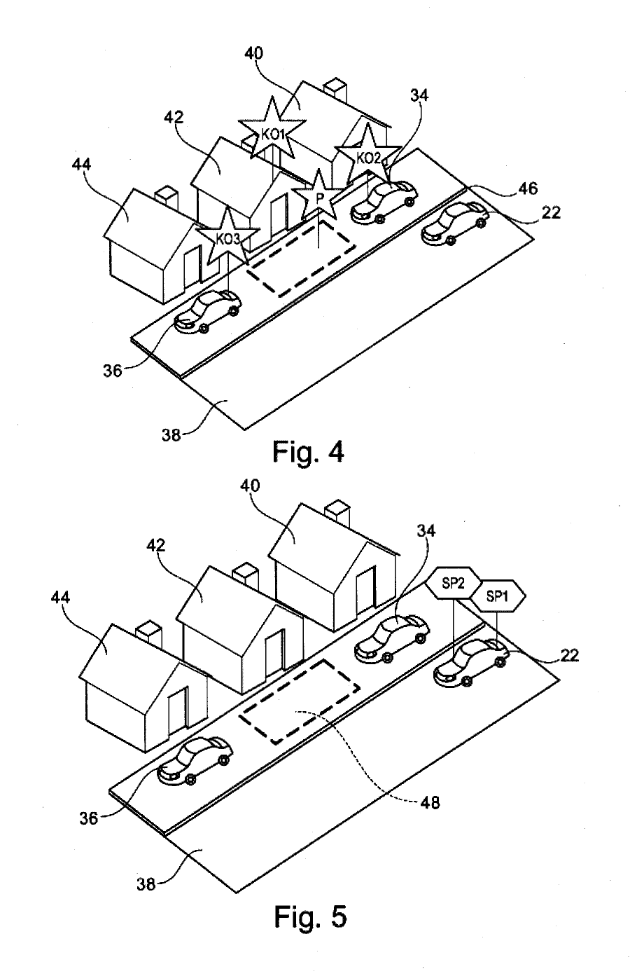

Definition of the validation points is represented in block 30. For judgment of the test, the designer wishes to ensure that the tested vehicle 22 parks on the parking space 48 without touching the two parked vehicles 34, 36 and surrounding houses 40, 42, 44. To enable a dedicated evaluation, the test designer will assign the following validation marks, see FIG. 4: a KO validation marker KO1 to the houses 40, 42, 44, a KO validation marker to the first (rear) parked vehicle 34 (KO2), a KO validation marker to the second (front) parked vehicle 36 (KO3), and a positive validation marker to the parking space 48, which is linked to a score of 1. Every time the tested vehicle 22 is capable of reaching the parking space 48 correctly, a score of 1 is given.

In addition, the test designer wishes to check acceleration and a possible jerking driving of the tested vehicle 22 during a maneuver, and confirm that these parameters are within a predefined tolerance, which is typical for vehicles of a relevant producer or is defined by other attributes. To enable this, the test designer will deactivate all other traffic and comfort rules except for the comfort rules that are linked to acceleration and jerking.

Definition of a manner of drive, i.e., drive command points is represented in block 28, see FIG. 5. Only one starting point is necessary. It is presumed that the tested vehicle 22 is stopped at the starting point. The starting point (SP1) is assigned to the tested vehicle 22. A software activation point (SP2) is also assigned to the tested vehicle 22. This software activation point contains an item of information on the tested vehicle 22, which enables it to start and to activate the parking assistance system. Every time a system ends a maneuver of parking, or has ended in a situation where the system can do nothing more, the test is analyzed, stopped, and a next test begins.

Analysis is represented in block 32. The test designer can now start the 71,424 total tests. He can do so, for example, in such a manner that a corresponding computer is active overnight. The system executes, automatically, all combinations that are defined by at least one variation point and at least one drive command point. The runtime can be optimized by removing a variation linked to the tested vehicle 22 as soon a corresponding combination has achieved a KO point. The following judgment can be derived from the above-described example:

If the tested vehicle 22 touches an arbitrary KO point, an associated variation of the tested vehicle 22 is considered to be failed.

An associated variation is considered passed if the tested vehicle 22 reaches a positive point that is linked to the parking space 48 for each test performance in every specific variation. Since there are 16 variations that are linked to the tested vehicle 22, a score of 4464 is to be achieved. Otherwise, an optimization is to be carried out depending on a result.

With the result, a development team can now support or exclude, respectively, specific parking sensor, braking, and strategy algorithms.

The test environment comprises models of every part of the tested vehicle 22 (sensors, actuators . . . ) and follows laws of physics. It is possible to link control software to the tested vehicle 22. The test method is carried out according to scientific rules of game theory.

The disclosure describes methods for practical checking of a tested vehicle 22, which is equipped with automated driving software that is implemented comprising the following parts, which can be used in the virtual test environment: a virtual test scenario, at least one variation point or marker, at least one validation point or marker, at least one drive command point or marker, an evaluation method, which preferably relates to a scoring, and a virtual reality environment that enables the test to be defined.

The disclosure furthermore describes methods and algorithms that define the virtual test scenario, in this case the test scenario comprises at least one active virtual road user, at least one passive road user, and a virtual test environment, obtained from a library.

A variation point is an element of the VR environment that can be linked to every object of the virtual test scenario. A variation point enables access to features or properties of a test scenario object to which the variation point was assigned. A variation point enables a value, or a value range for at least one of the properties of the test scenario object to be defined or established, with which the variation point was associated. Multiple variation points can be linked to one object. In one preferred embodiment, the variation point, or marker is positioned via a VR environment. A property that can be accessed by a variation point is a control algorithm, a parameter value, a model, etc.

A validation point is an element of the VR environment that can be linked to every object of the virtual test scenario. A validation point is an element that can be collected by the tested vehicle 22 in event of contact between the tested vehicle 22 and the element assigned to the validation point. This can be either as soon as contact is established, or can apply for a certain duration of the contact. A validation point can be a positive validation point that is associated with a positive score, in order to indicate an element with which the tested vehicle 22 is supposed to interact. A validation point can be a negative validation point that is linked to a negative score, in order to indicate an element to which the tested vehicle 22 is not supposed to come excessively close, or with which the tested vehicle 22 is not supposed to critically interact. A validation point can be a KO validation point that indicates an element with which the tested vehicle 22 can never interact, otherwise an entire test is considered to be failed. A validation point is used by the test system in order to judge the tests.

A drive command point is an element of the VR environment that can be positioned at every arbitrary location of the virtual test scenario, and, in particular, on a test environment element (road 38, curbstone 46 . . . ), or can be linked to an element of the virtual test scenario. A drive command point can be at least one starting point for the tested vehicle 22. A drive command point, or travel instruction point can be at least one waypoint that the tested vehicle 22 is supposed to reach. A drive command point can be at least one software activation point or event activation point, which is linked to an element of the virtual test scenario that indicates that a specific item of software, parameter, actuator, strategy . . . of this element is to be activated (for example, assistant for parking). A drive command point can be linked to a certain activation probability and/or begin with a time delay.

An evaluation method consists of counting the score linked to the validation points and outputting it. An evaluation method consists of monitoring an occurrence of KO validation points. If a KO validation point is received, all of the test variations that are linked to a configuration of the vehicle to be tested are considered as failed, and remaining tests that are linked to the configuration can be skipped by the system. An evaluation method consists of counting the score per configuration of subject matter to be tested, and outputting it. The evaluation can provide a scaling over a number of the tests, and over a number of the tests with a specific configuration of the checked vehicle 22.

An evaluation method consists of defining a classification of the traffic rules and the associated score. This rule catalog is generic, can be reused for every type of test, and could be part of a standard that is available to every vehicle producer. It is possible to configure which rules are to be judged for a test or not.

A judgment method consists of defining a classification of “comfort rules” and scores linked thereto. This catalog is generic and can be used for every type of test. The catalog is generally specific for each vehicle producer, since a certain driving feeling and behavior are specified by the producer. It is possible to select which rule is not to be taken into consideration for a test.

Definition is understood as inputting a value, establishing or selecting a parameter.

The applicant reserves the right to combine features from sets of the description, and also parts of the sets, and from claims, also individual features from claims here, with one another as desired. This combination can also be independent of the features of the independent and dependent claims.

While exemplary embodiments are described above, it is not intended that these embodiments describe all possible forms of the disclosure. Rather, the words used in the specification are words of description rather than limitation, and it is understood that various changes may be made without departing from the spirit and scope of the disclosure. Additionally, the features of various implementing embodiments may be combined to form further embodiments of the disclosure.

What is claimed is:

1. A method for virtually testing a vehicle comprising:
operating an autonomously driving, tested vehicle in a virtual environment using a computer;
operating a virtual test scenario for the tested vehicle in the virtual environment using the computer by defining at least one variation point that derives a number of tests from the virtual test scenario, at least one validation point that marks an element of the virtual environment, and activating at least one drive command point that instructs control of the tested vehicle tested; and
analyzing each of the variation, validation and drive command points to generate a score indicative of a performance of the tested vehicle in the test scenario.

2. The method as claimed in claim 1 further comprising evaluating each virtual test scenario, and using an interface to define the variation, validation and drive command points of the test scenario.

3. The method as claimed in claim 2, wherein the interface is a virtual reality input.

4. The method as claimed in claim 1, wherein the virtual test scenario is programmed according to game theory.

5. The method as claimed in claim 1, wherein for the virtual test scenario is defined to associate sensors and actuators with the tested vehicle.

6. The method as claimed in claim 1 further comprising associating a probability for a performance of the at least one drive command point with at least one of the drive command points and a certain time delay.

7. The method as claimed in claim 1, wherein the computer includes multiple partial computers.

8. A computer that tests a vehicle, comprising:
a virtual test scenario for an autonomously driving tested vehicle having a variation point and a special validation point to mark an element of a virtual environment; and
an analyzing unit configured to compare the variation and special validation points to generate a score indicative of a performance of the tested vehicle in the virtual test scenario.

9. The computer as claimed in claim 8 further comprising a virtual reality interface configured to output the virtual test scenario in the virtual environment.

10. The computer as claimed in claim 8, wherein the virtual test scenario includes at least one drive command point to instruct activation of the tested vehicle.

11. The computer as claimed in claim 8 further comprising a library configured to store different test scenarios and elements to test the tested vehicle using the different test scenarios and elements and generate a score indicative of a performance of the tested vehicle.

12. The computer as claimed in claim 11, wherein the test scenario includes at least one active virtual road user, at least one passive road user, and the virtual environment being obtained from the library.

13. An autonomously driving test system comprising:
a computer that generates, for a vehicle, a virtual test scenario having variation, validation and drive command points to mark an element of a virtual environment and control vehicle activations to test the vehicle; and
an analyzing unit configured to compare the points to generate a score indicative of a performance of the tested vehicle related to the element of the virtual environment in the virtual test scenario.

14. The autonomously driving test system as claimed in claim 13 further comprising a virtual reality interface configured to output the virtual test scenario in the virtual environment.

15. The autonomously driving test system as claimed in claim 13 further comprising a library configured to store different test scenarios and elements to test the tested vehicle to generate a score indicative of a performance of the tested vehicle across the different test scenarios and elements.

16. The autonomously driving test system as claimed in claim 15, wherein the virtual test scenario, being obtained from the library, includes at least one active virtual road user, at least one passive road user, and the virtual environment.
